(19) United States
(12) Patent Application Publication
(10) Pub. No.: US 2026/0182352 A1
(43) Pub. Date: Jun. 25, 2026

(54) TWO-DIMENSIONAL LINER-BASED RESISTANCE REDUCTION FOR SUBTRACTIVE PATTERNING

(71) Applicant: International Business Machines Corporation, Armonk, NY (US)

(72) Inventors: Darsith Jayachandran, Menands, NY (US); Ruilong Xie, Niskayuna, NY (US); Koichi Motoyama, Clifton Park, NY (US); Oleg Gluschenkov, Tannersville, NY (US)

(21) Appl. No.: 19/000,657

(22) Filed: Dec. 23, 2024

(51) Int. Cl. H01L 23/532; H01L 21/768

(52) U.S. Cl. CPC H10W 20/44; H10W 20/039

(57) ABSTRACT

Semiconductor devices having a 2D liner for resistance reduction using subtractive patterning are provided. In one aspect, a semiconductor device includes: an FET; a source/drain contact to a source/drain region of the FET; a top via in direct contact with the source/drain contact, where the source/drain contact and the top via each has an upwardly tapered profile; and a liner of a 2D material disposed on the source/drain contact and on the top via. A metal layer can be disposed over the source/drain contact and on the top via, which includes an interconnect that contacts the top via. A method of fabricating the present semiconductor devices is also provided.

### BACKGROUND

The present invention relates generally to the electrical, electronic and computer arts and, more particularly, to semiconductor devices having a two-dimensional (2D) liner for resistance reduction, and techniques for fabrication thereof using subtractive patterning.

Interconnects are used to make connections between various components of a semiconductor device. Typically, a liner is employed as a barrier to prevent diffusion of metals from the interconnects into the surrounding materials.

However, with continued device scaling and hence shrinking interconnect dimensions, factors such as resistance become a significant roadblock to advancing device performance. In that regard, the particular materials and how they are used in interconnect fabrication can become an important design consideration.

### BRIEF SUMMARY

Principles of the invention provide semiconductor devices having a two-dimensional (2D) liner for resistance reduction, and techniques for fabrication thereof using subtractive patterning. In one aspect, a semiconductor device is provided. The semiconductor device includes: a field-effect transistor (FET); a source/drain contact to a source/drain region of the FET; a top via in direct contact with the source/drain contact, where the source/drain contact and the top via each has an upwardly tapered profile; and a liner of a two-dimensional (2D) material disposed on the source/drain contact and on the top via.

In another aspect, another semiconductor device is provided. The semiconductor device includes: a FET; a source/drain contact to a source/drain region of the FET; a top via in direct contact with the source/drain contact, where the source/drain contact and the top via each has an upwardly tapered profile; a liner of a 2D material disposed on the source/drain contact and on the top via; and a metal layer disposed over the source/drain contact and on the top via, wherein the metal layer includes an interconnect that contacts the top via.

In yet another aspect, a method of fabricating a semiconductor device is provided. The method includes: depositing a contact metal over a source/drain region of an FET; subtractively patterning the contact metal into a source/drain contact to the source/drain region, and a top via in direct contact with the source/drain contact; and depositing a liner of a 2D material onto the source/drain contact and onto the top via.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
A two-dimensional (2D) liner on subtractively-patterned interconnects;
Whereby the 2D liner provides reduced resistance due to a reduction in surface scattering;
Whereby the 2D liner also serves as a diffusion barrier in advanced interconnect technologies; and
Whereby the 2D liner can further provide an alternative conducting path for the flow of charge carriers.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-15 are cross-sectional diagrams illustrating the fabrication of an exemplary semiconductor device, according to aspects of the invention, where FIG. 1 is a top-down view and the remaining figures are X or Y cross-sectional views.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

As highlighted above, scaling the dimensions of the interconnect architecture in semiconductor devices brings into focus aspects like interconnect resistance as significant challenges to enhancing device performance. Namely, with use of smaller conductors such as thinner interconnect metal lines comes a higher resistance. Advantageously, it has been found herein that two-dimensional (2D) van der Waals materials such as graphene are promising liner materials not only as diffusion barriers in advanced, i.e., thinner, interconnect technologies, but also as a means to reduce resistance in these structures.

More specifically, 2D materials such as graphene help to reduce surface scattering, thereby reducing interconnect resistance. Namely, surface scattering occurs when charge carriers travelling through a conductor such as an interconnect are ‘scattered’ upon collision with the interconnect surface, thereby causing them to lose energy. Such surface scattering increases the interconnect resistance. Scaling further magnifies the effects of surface scattering as a greater percentage of the charge carriers in a smaller interconnect are impacted by this phenomenon. A 2D liner such as graphene reduces surface scattering by providing a smooth, reflective surface that deflects charge carriers back along their travel path.

Also, 2D materials such as graphene can provide an alternative conducting path, thereby reducing the overall resistance through the present interconnects. For instance, lateral charge transfer from the interconnect to the 2D liner provides the charge carriers with another conducting path along the interconnect. Further, as will be described in detail below, embodiments are also contemplated herein where edge injection is leveraged to introduce charge carriers directly into the present 2D liner from an adjacent metal level.

The term ‘2D materials’ as used herein generally refers to any material whose thickness is less than 3 nanometers (nm) and/or is formed as layers of sheets of atoms. The sheet can extend over any desired length and width. Throughout the sheet these carbon atoms are bonded by strong covalent bonds. By contrast, weak van der Waals forces can hold multiple sheets together. As will be described in detail below, it is this unique construction of the present 2D (van der Waals) materials that is leveraged herein to provide the above-described alternative conducting path.

The present techniques are generally applicable to the use of any 2D materials as a liner. However, by way of example only, suitable 2D materials for use in accordance with the present techniques include, but are not limited to, carbon-containing materials such as graphene and/or graphene oxide, hexagonal boron nitride (h-BN), and/or transition metal dichalcogenides (e.g., with the formula MX2 where M is a transition metal selected from molybdenum (Mo), tungsten (W) and/or vanadium (V), and where X is a chalcogen selected from sulfur(S), selenium (Se) and/or tellurium (Te)).

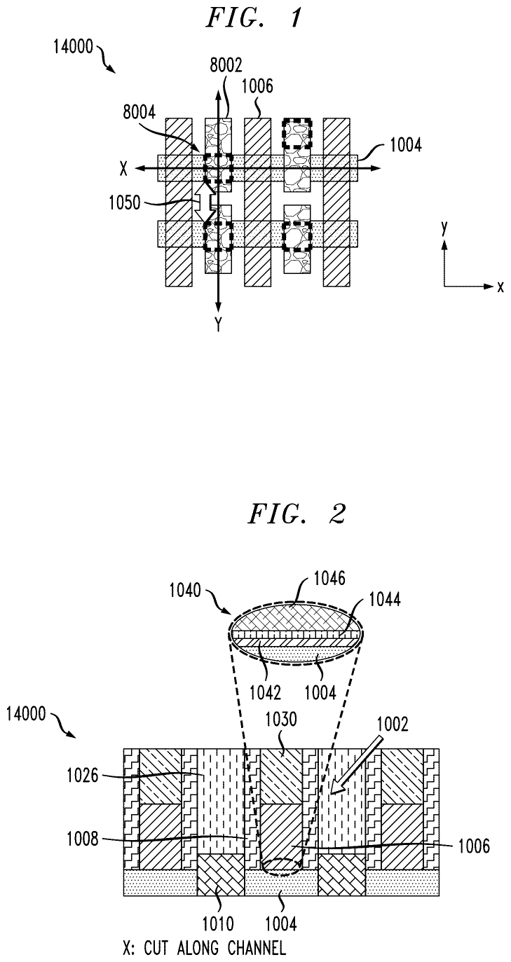

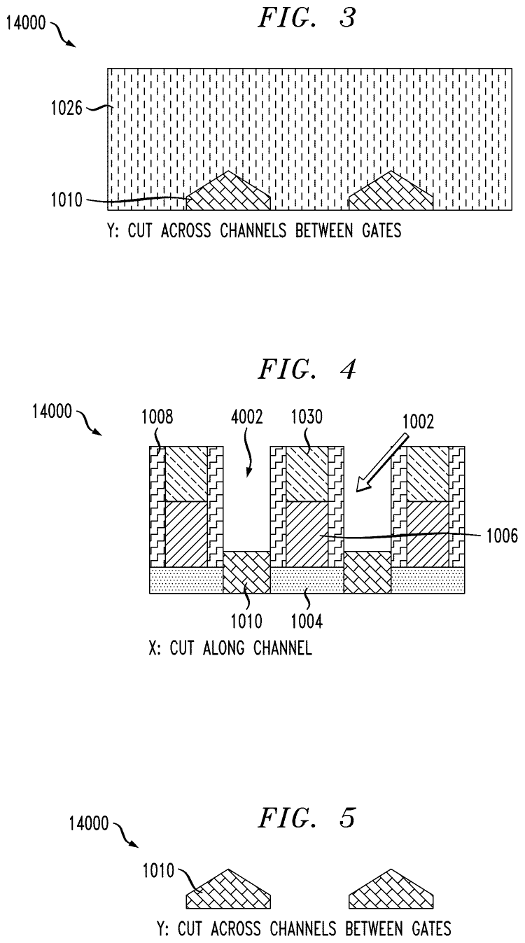

Given the above overview, an exemplary methodology for fabricating a semiconductor device 14000 in accordance with the present techniques is now described by way of reference to FIGS. 1-15. For instance, referring to FIG. 1 (a top-down view), FIG. 2 (an X cross-sectional view), and FIG. 3 (a Y cross-sectional view), the process begins with the formation of a gate cap 1030 over a gate 1006 of each field-effect transistor (FET) 1002 of the semiconductor device 14000. Namely, according to an exemplary embodiment, each FET 1002 includes the gate 1006 over a channel 1004, and source/drain regions 1010 at opposite ends of the channel 1004 which are offset from the gate 1006 by gate spacers 1008. An interlayer dielectric 1026 is disposed over the source/drain regions 1010.

As shown particularly in FIG. 1, the semiconductor device 14000 can include multiple channels 1004 and multiple gates 1006 oriented orthogonal to one another, and extending arbitrarily along an X-direction and a Y-direction, respectively. Accordingly, the X cross-sectional views provided herein represent cuts through the semiconductor device 14000 in the X-direction, i.e., along one of the channels 1004. The Y cross-sectional views represent cuts through the semiconductor device 14000 in the Y-direction, i.e., across the channels 1004 between two of the gates 1006.

Further, as will be described in detail below, subtractive patterning will be used herein to form contacts to the source/drain regions 1010 (i.e., source/drain contacts 8002), and top vias 8004 in direct contact with the source/drain contacts 8002. This process enables both the top vias 8004 and the source/drain contacts 8002 to have a unique upwardly tapered profile (which is wider at the bottom and narrower/tapered at the top). Advantageously, this upwardly tapered profile increases the spacing between adjacent FETs (i.e., the FET-2-FET space, see arrow 1050 in FIG. 1) as compared to a conventional architecture, which is a considerable benefit especially in scaled designs where this FET-2-FET space is at a premium.

It is notable that, for ease and clarity of depiction, not all of the features of the semiconductor device 14000 are shown in FIG. 1. In FIG. 1 for instance, structures such as the above-mentioned gate caps 1030, the interlayer dielectric 1026, etc. are not included in order to show the orientation of the channels 1004 and the gates 1006, and the positioning of the source/drain contacts 8002 and associated top vias 8004.

In general, any type of planar or non-planar FET design can be employed in accordance with the present techniques. However, in one exemplary embodiment, each FET 1002 has a non-planar architecture such as a nanosheet FET or a fin FET. As would be apparent to one of ordinary skill in the art, a nanosheet FET includes a stack of active layers (in this case nanosheets) which serve as the channels of the FET, and a gate which can surround at least a portion of each of the channels in a gate-all-around or GAA configuration. In that case, the channels 1004 shown in the figures would be representative of the top nanosheet in the stack. Fin FETs, on the other hand, have fin-shaped channels over which the gates are disposed. With that scenario, the channels 1004 shown in the figures would be representative of the top portion of a fin. The channels 1004 can be formed from any suitable semiconductor material including, but not limited to, silicon (Si), silicon germanium (SiGe) and/or a III-V material.

In one illustrative, non-limiting example, the gates 1006 are high-k metal gates formed using a gate-last process. As would be apparent to one of ordinary skill in the art, a gate-last process involves forming sacrificial gates (not shown as they are no longer present at this point in the process flow) of, e.g., polysilicon and/or amorphous silicon, early on in the process which serve as placeholders, and enable the placement of other components such as the source/drain regions 1010. The term “sacrificial” as used herein refers to a material or structure that is used in one part of the process, and then later removed, in whole or in part, during fabrication of the semiconductor device 14000. Advantageously, the use of a gate-last process avoids exposing the high-K metal gate materials such as high-K gate dielectrics to potentially damaging conditions like the high temperatures experienced during formation of the source/drain regions 1010. Accordingly, following placement of the source/drain regions 1010, the sacrificial gates are removed and ‘replaced’ with the final or high-K metal gates of the device.

For instance, referring to magnified view 1040 of FIG. 2, in this non-limiting example gates 1006 include a (conformal) gate dielectric 1042 disposed on the channels 1004, at least one workfunction-setting metal 1044 disposed on the gate dielectric 1042, and an optional (low-resistance) fill metal 1046 disposed on the workfunction-setting metal(s) 1044. According to an exemplary embodiment, the gate dielectric 1042 is a high-K material. The term “high-K,” as used herein, refers to a material having a relative dielectric constant k which is much higher than that of silicon dioxide (e.g., a dielectric constant K=25 for hafnium oxide (HfO₂) rather than 4 for SiO₂). Suitable high-K gate dielectrics include, but are not limited to, hafnium oxide (HfO₂) and/or lanthanum oxide (La₂O₃). A process such as chemical vapor deposition (CVD), atomic layer deposition (ALD), or physical vapor deposition (PVD) can be employed to deposit the gate dielectric 1042. According to an exemplary embodiment, the gate dielectric 1042 has a thickness of from about 1 nanometer (nm) to about 5 nm. A reliability anneal can be performed following deposition of the gate dielectric 1042. In one exemplary embodiment, the reliability anneal is performed at a temperature of from about 500 degrees Celsius (° C.) to about 1200° C., for a duration of from about 1 nanosecond to about 30 seconds. Preferably, the reliability anneal is performed in the presence of an inert gas such as, but not limited to, nitrogen.

The at least one workfunction-setting metal 1044 can include an n-type workfunction-setting metal and/or a p-type workfunction-setting metal. Suitable n-type workfunction-setting metals include, but are not limited to, titanium nitride (TiN), tantalum nitride (TaN) and/or aluminum (Al)-containing alloys such as titanium aluminide (TiAl), titanium aluminum nitride (TiAlN), titanium aluminum carbide (TiAlC), tantalum aluminide (TaAl), tantalum aluminum nitride (TaAlN), and/or tantalum aluminum carbide (TaAlC). Suitable p-type workfunction-setting metals include, but are not limited to, TiN, TaN, and/or tungsten (W). TiN and TaN are relatively thick (e.g., greater than about 2 nm) when used as p-type workfunction-setting metals. However, very thin TiN or TaN layers (e.g., less than about 2 nm) may also be used beneath Al-containing alloys in n-type workfunction-setting stacks to improve electrical properties such as gate leakage currents. Thus, there is some overlap in the exemplary n- and p-type workfunction-setting metals given above. A process such as CVD, ALD or PVD can be employed to deposit the workfunction-setting metal(s) 1044, after which the metal overburden can be removed using a process such as chemical-mechanical planarization (CMP).

The optional fill metal 1046 can be used to fill in any remaining spaces in the gates 1006. Suitable (low-resistance) fill metals 1046 include, but are not limited to, W, cobalt (Co), ruthenium (Ru) and/or Al which can be deposited using a process or combination of processes including, but not limited to, CVD, ALD, PVD, sputtering, plating, evaporation, ion beam deposition, electron beam deposition, laser assisted deposition, chemical solution deposition, etc.

According to an exemplary embodiment, the source/drain regions 1010 are each formed from an n-type or p-type in-situ doped (i.e., during growth) or ex-situ doped (e.g., via ion implantation) epitaxial material such as epitaxial Si, epitaxial SiGe, etc. Suitable p-type dopants include, but are not limited to, boron (B). Suitable n-type dopants include, but are not limited to, phosphorous (P) and/or arsenic (As).

Suitable interlayer dielectric 1026 materials include, but are not limited to, silicon nitride (SiN), silicon oxycarbide (SiOC) and/or oxide low-K materials such as silicon oxide (SiOx) and/or oxide ultralow-K interlayer dielectric (ULK-ILD) materials, e.g., having a dielectric constant k of less than 2.7. Suitable ultralow-κ dielectric materials include, but are not limited to, porous organosilicate glass (pSiCOH). A process such as CVD, ALD or PVD can be used to deposit the interlayer dielectric 1026, after which the interlayer dielectric 1026 can be planarized using a process such as CMP.

In general, the gate caps 1030 can be formed from any material that provides etch selectivity vis-à-vis the interlayer dielectric 1026. That way, the gates 1006 will be covered during the subsequent recess of the interlayer dielectric 1026 (see below). By way of example only, suitable materials for the gate caps 1030 include, but are not limited to, oxide and nitride dielectrics such as SiN, SiOx and/or silicon oxynitride (SiOxNy), which can be deposited using a process such as CVD, ALD or PVD. Following deposition, the material can be planarized using a process such as CMP.

Referring to FIG. 4 (an X cross-sectional view) and FIG. 5 (a Y cross-sectional view), the interlayer dielectric 1026 is then recessed. As provided above, the interlayer dielectric 1026 can be formed from an oxide or nitride material. In that case, the recess of the interlayer dielectric 1026 can be performed using an oxide- or nitride-selective etching process. The recess of the interlayer dielectric 1026 forms trenches 4002 over and exposing the underlying source/drain regions 1010.

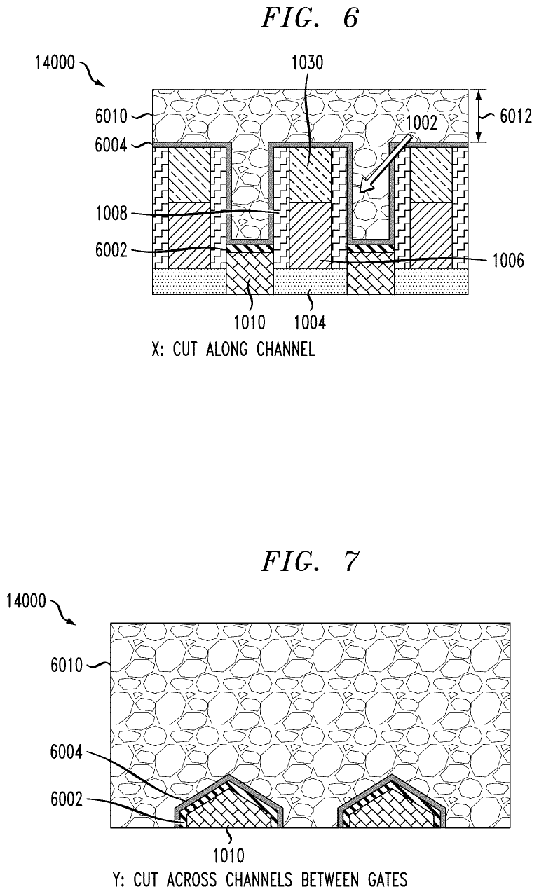

Referring to FIG. 6 (an X cross-sectional view) and FIG. 7 (a Y cross-sectional view), a contact metal 6010 is deposited onto the gate spacers 1008 and gate cap 1030, and into the trenches 4002 over the source/drain regions 1010. Suitable contact metals 6010 include, but are not limited to, tungsten (W), cobalt (Co), ruthenium (Ru), molybdenum (Mo), rhodium (Rh) and/or iridium (Ir), which can be deposited using a process or combination of processes including, but not limited to, CVD, ALD, PVD, sputtering, plating, evaporation, ion beam deposition, electron beam deposition, laser assisted deposition, chemical solution deposition, etc.

Prior to depositing the contact metal 6010, in one exemplary embodiment a trench silicide 6002 is first formed on the source/drain regions 1010 within the trenches 4002, followed by the conformal deposition of a metal adhesion layer 6004 over the trench silicide 6002 and lining the trenches 4002. As would be apparent to one of ordinary skill in the art, the term ‘silicide’ generally refers to the combination of silicon with another element, oftentimes a metal. For instance, by way of example only, the trench silicide 6002 can be formed by depositing a metal such as titanium (Ti), nickel (Ni), platinum (Pt) and/or nickel platinum (NiPt) onto the source/drain regions 1010 using a process such as CVD, ALD or PVD, and then performing an anneal to generate the corresponding, e.g., Ni, Pt, or NiPt, trench silicide 6002. Depending on the composition of the source/drain regions 1010 (see above) the trench silicide 6002 may also contain germanium, and thus may be a germanium silicide. According to an exemplary embodiment, the trench silicide 6002 has a thickness of from about 1 nm to about 5 nm.

Suitable materials for the metal adhesion layer 6004 include, but are not limited to, TiN and/or TaN, which can be deposited using a process such as CVD, ALD or PVD. According to an exemplary embodiment, the metal adhesion layer 6004 has a thickness of from about 1 nm to about 5 nm.

As shown particularly in FIG. 6, the contact metal 6010 is deposited so as to overfill the trenches 4002 such that a portion 6012 of the contact metal 6010 is present over and above the gate spacers 1008/gate cap 1030. As will be described in detail below, this portion 6012 of the contact metal 6010 will be used to form the top vias 8004 during the present subtractive patterning-based process for contact formation.

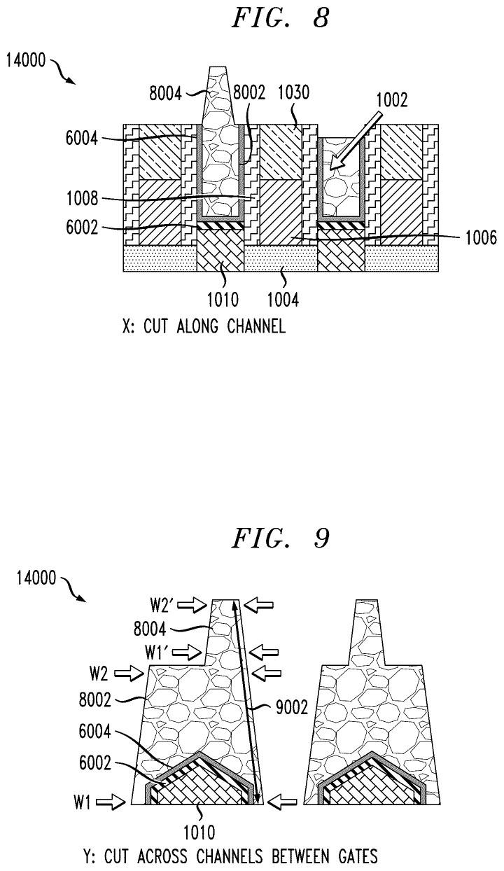

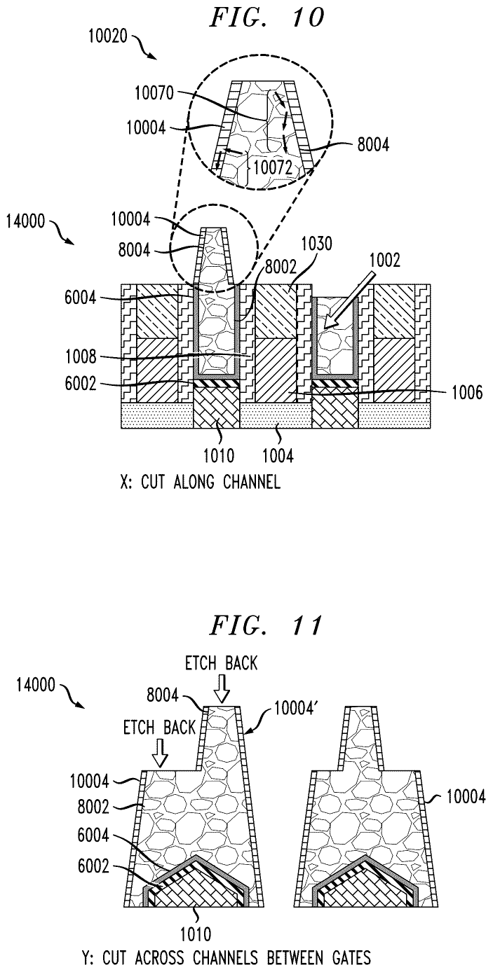

Referring to FIG. 8 (an X cross-sectional view) and FIG. 9 (a Y cross-sectional view), subtractive patterning is then used to pattern the contact metal 6010 into the source/drain contacts 8002 and the top vias 8004. With a subtractive patterning process, a layer of material (in this case the contact metal 6010) is blanket deposited, followed by an etch which is used to pattern the material into individual structures such as the source/drain contacts 8002 and top vias 8004 shown in FIGS. 8 and 9. By comparison, an additive process, such as a damascene or dual-damascene technique, creates a structure by adding material to an existing pattern.

Standard lithography and etching techniques can be employed to pattern the contact metal 6010 into the source/drain contacts 8002 and the top vias 8004. With standard lithography and etching techniques, a lithographic stack (not shown), e.g., photoresist/anti-reflective coating/organic planarizing layer, is used to pattern a hardmask (not shown) with the footprint and location of, in this case, the source/drain contacts 8002 and the top vias 8004. Suitable hardmask materials include, but are not limited to, silicon nitride (SiN), silicon dioxide (SiO₂) (including low temperature oxides or LTOs deposited at a temperature of from about 400° C. to about 450° C.), titanium nitride (TiN) and/or silicon oxynitride (SiON). An etch is then performed to transfer the pattern from the hardmask to the underlying contact metal 6010. Suitable etching processes include, but are not limited to, directional (anisotropic) etching processes such as reactive ion etching (RIE). Alternatively, the hardmask can be formed by other suitable techniques, including but not limited to, sidewall image transfer (SIT), self-aligned double patterning (SADP), self-aligned quadruple patterning (SAQP), and other self-aligned multiple patterning (SAMP).

As shown FIGS. 8 and 9, the present subtractive patterning process results in the top vias 8004 and the source/drain contacts 8002 having a unique upwardly tapered profile, whereby each of the source/drain contacts 8002 and each of the top vias 8004 is wider at the bottom and narrower/tapered at the top. For instance, referring to FIG. 9, the bottom of each of the source/drain contacts 8002 (in this case an end of each of the source/drain contacts 8002 adjacent to the source/drain regions 1010) has a width W1, and the top of each of the source/drain contacts 8002 (in this case an end of each of the source/drain contacts 8002 opposite the source/drain regions 1010) has a width W2, where W1 is greater than (>) W2. Similarly, the bottom of each of the top vias 8004 (in this case an end of each of the top vias 8004 directly contacting the source/drain contacts 8002) has a width W1′, and the top of each of the top vias 8004 (in this case an end of each of the top vias 8004 opposite the source/drain contacts 8002) has a width W2′, where W1′>W2′.

Depending on their positioning, the top vias 8004 and the source/drain contacts 8002 can share a common sidewall 9002. As will be described in detail below, this common sidewall 9002 can be leveraged to provide a continuous layer of the present 2D material-based liner alongside both the top vias 8004 and the source/drain contacts 8002. As highlighted above, doing so advantageously provides an alternative conducting path for the flow of charge carriers.

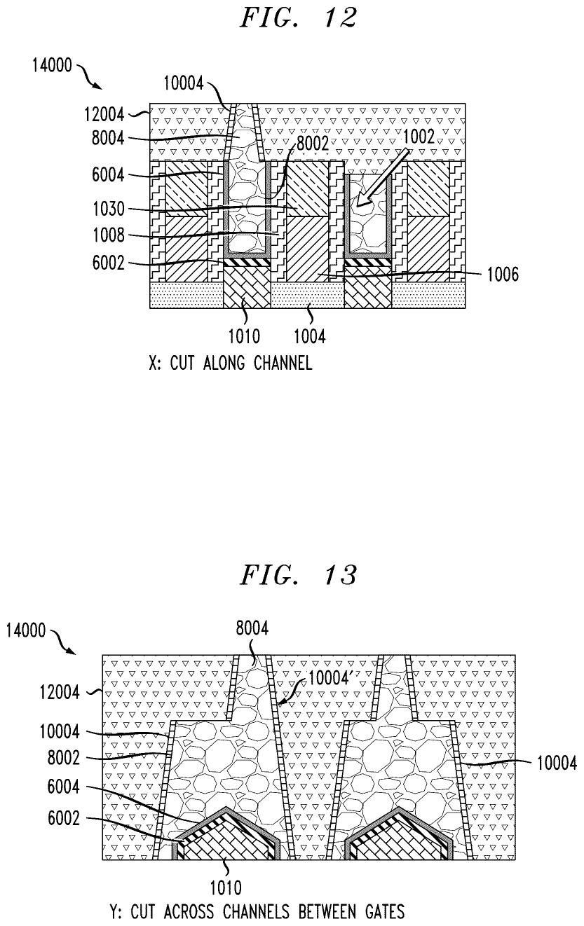

Referring to FIG. 10 (an X cross-sectional view) and FIG. 11 (a Y cross-sectional view), a liner 10004 is then deposited onto exposed surfaces of the source/drain contacts 8002 and the top vias 8004. As highlighted above, the liner 10004 is formed from a 2D material such as, but not limited to, graphene, graphene oxide, hexagonal boron nitride and/or a transition metal dichalcogenide (e.g., having the formula MX2 where M is a transition metal selected from Mo, W and/or V, and where X is a chalcogen selected from S, Se and/or Te). By way of example only, such 2D materials can be deposited onto the source/drain contacts 8002 and the top vias 8004 via a layer transfer process. For instance, the 2D material is first grown on a donor substrate (not shown) using a process such as CVD, followed by a transfer layer of a material like poly(methyl methacrylate) or PMMA (not shown). The transfer layer enables the donor substrate to then be removed, and the 2D material to be transferred to the exposed surfaces of the source/drain contacts 8002 and the top vias 8004. After which, the transfer layer can also be removed. Given the instant description, implementing such a layer transfer process in accordance with the present techniques would be apparent to one of ordinary skill in the art. According to an exemplary embodiment, the liner 10004 has a thickness of less than about 1.5 nm, e.g., from about 0.3 nm to about 0.6 nm.

Following deposition, an etch is then performed to ‘etch back’ the liner 10004, thereby removing the liner 10004 from horizontal surfaces of the source/drain contacts 8002 and the top vias 8004. See, for example, FIG. 11. Suitable etching processes include, but are not limited to, directional (anisotropic) etching processes such as RIE.

As provided above, the present (2D material-based) liner 10004 not only serves as an effective diffusion barrier, but also as a means to reduce surface scattering and hence resistance in the source/drain contacts 8002 and the top vias 8004. See arrows 10070 in the magnified view 10020 of FIG. 10.

As also shown particularly in FIG. 11, one segment 10004′ of the liner 10004 is continuous along the common sidewall 9002 (i.e., of one of the source/drain contacts 8002 and a respective one of the top vias 8004 as shown in FIG. 9). This provides the added advantage of an alternative conducting path for the flow of charge carriers (via lateral charge transfer as indicated by arrows 10072 in the magnified view 10020 of FIG. 10). This alternative conducting path helps to offset any increase in resistance associated with the reduction in contact area due to the above-described upwardly tapered profile. At the same time, the upwardly tapered profile improves the FET-2-FET spacing between adjacent FETs (see for example arrow 1050 in FIG. 1).

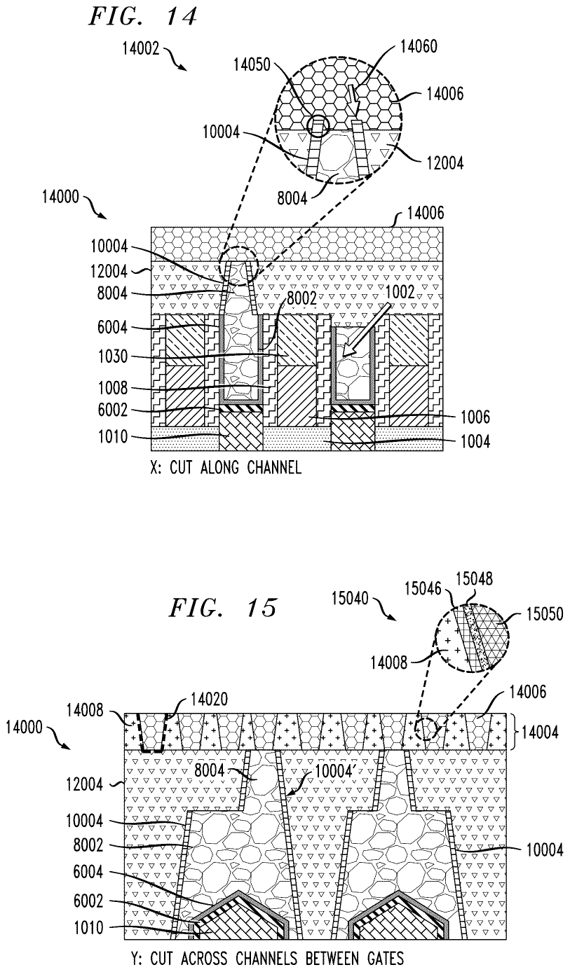

At least one additional metal level can then be built over the FETs 1002. To do so, an interlayer dielectric 12004 is first deposited over the source/drain contacts 8002 and the top vias 8004. See FIG. 12 (an X cross-sectional view) and FIG. 13 (a Y cross-sectional view). Suitable interlayer dielectric 12004 materials include, but are not limited to, SiN, SiOC and/or oxide low-K materials such as SiOx and/or oxide ULK-ILD materials such as pSiCOH. A process such as CVD, ALD or PVD can be used to deposit the interlayer dielectric 12004, after which the interlayer dielectric 12004 can be planarized using a process such as CMP which exposes the top vias 8004 and ends 14050 (see below) of the liner 10004.

Referring to FIG. 14 (an X cross-sectional view) and FIG. 15 (a Y cross-sectional view), a metal layer 14004 is then formed over the source/drain contacts 8002 and the top vias 8004. As shown particularly in FIG. 15, the metal layer 14004 includes interconnects 14006 embedded in a dielectric 14008. By way of example only, following deposition of the dielectric 14008 over the source/drain contacts 8002 and the top vias 8004, standard lithography and etching techniques (see above) can be employed to pattern features, e.g., trenches, in the dielectric 14008. See, for example, dashed outline 14020 which is exemplary of one of these features.

Standard metallization processes can then be employed to form the interconnects 14006, e.g., metal lines, in the features. For instance, referring to magnified view 15040 in FIG. 15, this metallization can include first depositing a silicide liner 15046 into and lining each of the features, depositing a metal adhesion layer 15048 onto the silicide liner 15046, and then depositing a fill metal 15050 onto the metal adhesion layer 15048. Suitable silicide liner 15046 materials include, but are not limited to, Ti, Ni and/or NiPt, which can be deposited using a process such as CVD, ALD or PVD. According to an exemplary embodiment, silicide liner 15046 has a thickness of from about 1 nm to about 5 nm. Suitable metal adhesion layer 15048 materials include, but are not limited to, TiN and/or TaN, which can be deposited onto the silicide liner 15046 using a process such as CVD, ALD or PVD. According to an exemplary embodiment, the metal adhesion layer 15048 has a thickness of from about 1 nm to about 5 nm. Suitable fill metals 15050 include, but are not limited to, W, Co, Ru and/or Al, which can be deposited onto the metal adhesion layer 15048 using a process such as CVD, ALD, PVD, sputtering, plating, evaporation, ion beam deposition, electron beam deposition, laser assisted deposition, chemical solution deposition, etc. Following deposition, the overburden can be removed using a process such as CMP.

Now present is the semiconductor device 14000 with the source/drain contacts 8002 and the top vias 8004 both having an upwardly tapered profile that is wider at the bottom than at the top. The top vias 8004 are in direct contact with the respective source/drain contacts 8002. The liner 10004 is formed from a 2D material disposed on the source/drain contacts 8002 and the top vias 8004. The metal layer 14004, disposed over the source/drain contacts 8002 and the top vias 8004, contains interconnects 14006 that contact the top vias 8004.

Embodiments are contemplated herein where the interconnects 14006 also contact the ends of the liner 10004. See, for example, magnified view 14002 in FIG. 14. Namely, in this example, the interconnects 14006 contact the top vias 8004 as well as an end 14050 of the liner 10004. The latter enables the introduction of charge carriers from the interconnects 14006 directly into the liner 10004 via edge injection. That combined with the liner 10004 being continuous along the common sidewall 9002 (see segment 10004′ of the liner 10004) advantageously provides an alternative conducting path for the flow of charge carriers, other than directly through the source/drain contacts 8002 and the top vias 8004. As indicated by arrow 14060, edge injection involves the introduction of charge carriers directly into the liner 10004 at an end/edge of the liner 10004. Due to their unique material structure, electric charge can easily move across sheets of the present 2D materials. With graphene, for instance, this is due to the presence of delocalized electrons in the lattice structure that provide a pathway for charge carriers across the material.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching, which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary semiconductor device 14000 includes: a field-effect transistor (FET) 1002; a source/drain contact 8002 to a source/drain region 1010 of the FET; a top via 8004 in direct contact with the source/drain contact, where the source/drain contact and the top via each has an upwardly tapered profile; and a liner 10004 of a two-dimensional (2D) material disposed on the source/drain contact and on the top via.

In accordance with other aspects of the present techniques, another exemplary semiconductor device 14000 includes: an FET 1002; a source/drain contact 8002 to a source/drain region 1010 of the FET; a top via 8004 in direct contact with the source/drain contact, where the source/drain contact and the top via each has an upwardly tapered profile; a liner 10004 of a 2D material disposed on the source/drain contact and on the top via; and a metal layer 14004 disposed over the source/drain contact and the top via, where the metal layer includes an interconnect 14006 that contacts the top via.

In accordance with further aspects of the present techniques, a method of fabricating a semiconductor device includes: depositing a contact metal 6010 over a source/drain region 1010 of an FET 1002; subtractively patterning the contact metal into a source/drain contact 8002 to the source/drain region, and a top via 8004 in direct contact with the source/drain contact; and depositing a liner 10004 of a 2D material onto the source/drain contact and onto the top via.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed 2D liner for resistance reduction using subtractive patterning.

An integrated circuit in accordance with aspects of the present inventions can be employed in essentially any application and/or electronic system where one or more aspects of the disclosed 2D liner for resistance reduction using subtractive patterning would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor device, comprising:
a field-effect transistor (FET);
a source/drain contact to a source/drain region of the FET;
a top via in direct contact with the source/drain contact, wherein the source/drain contact and the top via each has an upwardly tapered profile; and
a liner comprising a two-dimensional (2D) material disposed on the source/drain contact and on the top via.

2. The semiconductor device of claim 1, wherein one end of the source/drain contact adjacent to the source/drain region has a width W1 and another end of the source/drain contact opposite the source/drain region has a width W2, and wherein W1>W2.

3. The semiconductor device of claim 1, wherein one end of the top via in direct contact with the source/drain contact has a width W1′ and another end of the top via opposite the source/drain contact has a width W2′, and wherein W1′>W2′.

4. The semiconductor device of claim 1, wherein the liner is continuous along a common sidewall of the source/drain contact and the top via.

5. The semiconductor device of claim 1, wherein the 2D material is selected from the group consisting of: graphene, graphene oxide, hexagonal boron nitride, a transition metal dichalcogenide, and combinations thereof.

6. The semiconductor device of claim 5, wherein the 2D material comprises the transition metal dichalcogenide which has a formula MX₂, wherein M is a transition metal selected from the group consisting of: molybdenum (Mo), tungsten (W), vanadium (V), and combinations thereof, and wherein X is a chalcogen selected from sulfur(S), selenium (Se), tellurium (Te), and combinations thereof.

7. A semiconductor device, comprising:
a field-effect transistor (FET);
a source/drain contact to a source/drain region of the FET;
a top via in direct contact with the source/drain contact, wherein the source/drain contact and the top via each has an upwardly tapered profile;
a liner comprising a two-dimensional (2D) material disposed on the source/drain contact and on the top via; and
a metal layer disposed over the source/drain contact and the top via, wherein the metal layer comprises an interconnect that contacts the top via.

8. The semiconductor device of claim 7, wherein the interconnect also contacts an end of the liner.

9. The semiconductor device of claim 7, wherein one end of the source/drain contact adjacent to the source/drain region has a width W1 and another end of the source/drain contact opposite the source/drain region has a width W2, where W1>W2, and wherein one end of the top via in direct contact with the source/drain contact has a width W1′ and another end of the top via opposite the source/drain contact has a width W2′, where W1′>W2′.

10. The semiconductor device of claim 7, wherein the liner is continuous along a common sidewall of the source/drain contact and the top via.

11. The semiconductor device of claim 7, wherein the 2D material is selected from the group consisting of: graphene, graphene oxide, hexagonal boron nitride, a transition metal dichalcogenide, and combinations thereof.

12. The semiconductor device of claim 11, wherein the 2D material comprises the transition metal dichalcogenide which has a formula MX₂, wherein M is a transition metal selected from the group consisting of: Mo, W, V, and combinations thereof, and wherein X is a chalcogen selected from S, Se, Te, and combinations thereof.

13. A method of fabricating a semiconductor device, the method comprising:
depositing a contact metal over a source/drain region of a field-effect transistor (FET);
subtractively patterning the contact metal into a source/drain contact to the source/drain region, and a top via in direct contact with the source/drain contact; and
depositing a liner comprising a two-dimensional (2D) material onto the source/drain contact and onto the top via.

14. The method of claim 13, wherein the source/drain contact and the top via as subtractively patterned each has an upwardly tapered profile.

15. The method of claim 14, wherein one end of the source/drain contact adjacent to the source/drain region has a width W1 and another end of the source/drain contact opposite the source/drain region has a width W2, where W1>W2, and wherein one end of the top via in direct contact with the source/drain contact has a width W1′ and another end of the top via opposite the source/drain contact has a width W2′, where W1′>W2′.

16. The method of claim 13, wherein the liner as deposited onto the source/drain contact and the top via is continuous along a common sidewall of the source/drain contact and the top via.

17. The method of claim 13, wherein the 2D material is selected from the group consisting of: graphene, graphene oxide, hexagonal boron nitride, a transition metal dichalcogenide, and combinations thereof.

18. The method of claim 17, wherein the 2D material comprises the transition metal dichalcogenide which has a formula MX₂, wherein M is a transition metal selected from the group consisting of: molybdenum (Mo), tungsten (W), vanadium (V), and combinations thereof, and wherein X is a chalcogen selected from sulfur(S), selenium (Se), tellurium (Te), and combinations thereof.

19. The method of claim 13, further comprising:
forming a metal layer over the source/drain contact and the top via, wherein the metal layer comprises an interconnect that contacts the top via.

20. The method of claim 19, wherein the interconnect also contacts an end of the liner.
